(19) United States
(12) Patent Application Publication
(10) Pub. No.: US 2016/0149121 A1
(43) Pub. Date: May 26, 2016

(54) ELECTRONIC DEVICE AND METHOD FOR FABRICATING THE SAME

(71) Applicant: SK hynix Inc., Icheon-Si (KR)

(72) Inventors: Jae-Geun Oh, Icheon-Si (KR); Choon-Kun Ryu, Icheon-Si (KR); Hyung-Suk Lee, Icheon-Si (KR)

(21) Appl. No.: 14/789,841

(22) Filed: Jul. 1, 2015

(30) Foreign Application Priority Data
Nov. 24, 2014 (KR) 10-2014-0164511

(51) Int. Cl. H01L 43/12; H01L 43/02; G06F 13/40; G06F 3/06; G06F 12/08; H01L 27/22; H01L 43/10

(52) U.S. Cl. CPC H01L 43/12; H01L 27/228; H01L 43/02; H01L 43/10; G06F 3/0604; G06F 3/0646; G06F 3/0679; G06F 12/0802; G06F 13/4068; G06F 2212/202

(57) ABSTRACT

This technology provides an electronic device and method for fabricating the same. A method for fabricating an electronic device comprising a transistor includes forming a junction region which is partially amorphized in the semiconductor substrate at a side of the gate; forming a metal layer over the junction region; and performing a heat treatment process on the metal layer into a metal-semiconductor compound layer while crystallizing the junction region.

### CROSS-REFERENCE TO RELATED APPLICATION

This patent document claims priority and benefits of Korean Patent Application No. 10-2014-0164511, entitled “ELECTRONIC DEVICE AND METHOD FOR FABRICATING THE SAME” and filed on Nov. 24, 2014, which is incorporated herein by reference in its entirety.

### TECHNICAL FIELD

This patent document relates to memory circuits or devices and their applications in electronic devices or systems.

### BACKGROUND

Recently, as electronic devices or appliances trend toward miniaturization, low power consumption, high performance, multi-functionality, and so on, there is a demand for electronic devices capable of storing information in various electronic devices or appliances such as a computer, a portable communication device, and so on, and research and development for such electronic devices have been conducted. Examples of such electronic devices include electronic devices which can store data using a characteristic switched between different resistant states according to an applied voltage or current, and can be implemented in various configurations, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document provides memory circuits or devices and their applications in electronic devices or systems and various implementations of an electronic device, in which an electronic device can include a transistor having improved characteristics.

In one aspect, a method for fabricating an electronic device comprising a transistor includes forming a junction region which is partially amorphized in the semiconductor substrate at a side of the gate; forming a metal layer over the junction region; and performing a heat treatment process on the metal layer to change the metal layer into a metal-semiconductor compound layer while crystallizing the junction region.

Implementations of the above method may include one or more the following.

The forming of the junction region includes performing an ion implantation process at a temperature at or higher than 450° C. The performing of the ion implantation process includes implanting Si at a dose of about 5E14 ions/cm² to about 2E15 ions/cm² (i.e., from about 5×10¹⁴ ions/cm² to about 2×10¹⁵ ions/cm²) and an energy from about 1 KeV to about 10 keV. The performing of the ion implantation process includes implanting C at a dose of about 1E14 ions/cm² to about 2E15 ions/cm² (i.e., from about 1×10¹⁴ ions/cm² to about 2×10¹⁵ ions/cm²) and an energy from about 1 KeV to about 20 KeV. The performing of the ion implantation process includes implanting As at a dose of about 1E15 ions/cm² to about 1E16 ions/cm² (i.e., from about 1×10¹⁵ ions/cm² to about 1×10¹⁶ ions/cm²) and an energy from about 1 KeV to about 10 KeV. The performing of the ion implantation process includes implanting P at a dose of about 1E15 ions/cm² to about 2E16 ions/cm² (i.e., from about 1×10¹⁵ ions/cm² to about 2×10¹⁶ ions/cm²) and an energy from about 1 KeV to about 10 KeV. The metal-semiconductor compound layer includes a metal silicide. The method further comprises forming a conductive plug over the metal layer after the forming the metal layer and before the performing the heat treatment process. The conductive plug includes a metal nitride. The method further comprises forming a variable resistance element which is electrically coupled to the metal-semiconductor compound layer after the performing the heat treatment process. The variable resistance element includes two magnetic layers and a tunnel barrier layer interposed between the two magnetic layers.

In another aspect, an electronic device includes a transistor, and the transistor includes a semiconductor substrate in which a gate is formed; a junction region formed in the semiconductor substrate at a side of the gate; and a metal-semiconductor compound layer formed over the junction region, and wherein the junction region is in a crystallized state.

Implementations of the above electronic device may include one or more the following.

The electronic device further comprises a variable resistance element electrically coupled to the metal-semiconductor compound layer. The variable resistance element includes two magnetic layers and tunnel barrier layer interposed between the two magnetic layers.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the transistor is part of at least one of the control unit, the operation unit and the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the transistor is part of at least one of the core unit, the cache memory unit and the bus interface in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the transistor is part of at least one of the processor, the auxiliary memory device, the main memory device and the interface device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the transistor is part of at least one of the controller, the storage device, the temporary storage device and the interface in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the transistor is part of at least one of the memory controller, the memory, the buffer memory and the interface in the memory system.

These and other aspects, implementations and associated advantages are described in greater detail in the drawings, the description and the claims.

### BRIEF DESCRIPTION OF THE DRAWINGS

FIGS. 1 to 7 are views explaining a transistor and an example of a method for fabricating the same in accordance with an implementation.

FIGS. 8A to 8C are views obtained during a fabricating process of a transistor in accordance with a comparative example.

FIGS. 9A to 9C are views obtained during a fabricating process of a transistor in accordance with an implementation.

FIG. 10 is a plan view explaining a semiconductor memory in accordance with an implementation.

FIG. 11 is a cross-sectional view taken along a line C-C′ of FIG. 10.

FIGS. 12 and 13 are cross-sectional views explaining a transistor and an example of a method for fabricating the same in accordance with another implementation.

FIG. 14 is an example of configuration diagram of a microprocessor implementing memory circuitry based on the disclosed technology.

FIG. 15 is an example of configuration diagram of a processor implementing memory circuitry based on the disclosed technology.

FIG. 16 is an example of configuration diagram of a system implementing memory circuitry based on the disclosed technology.

FIG. 17 is an example of configuration diagram of a data storage system implementing memory circuitry based on the disclosed technology.

FIG. 18 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

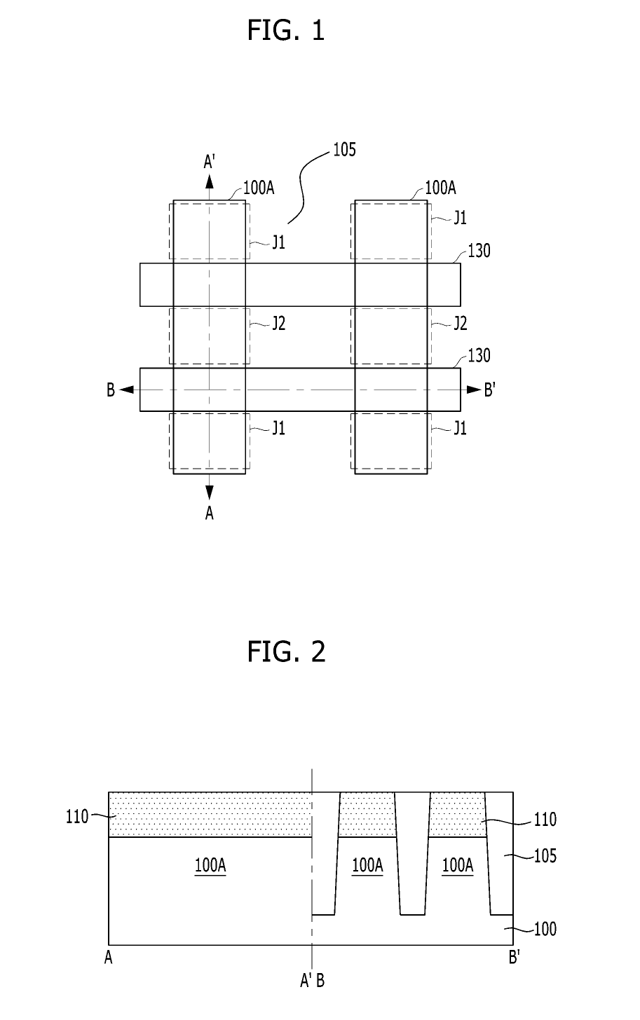

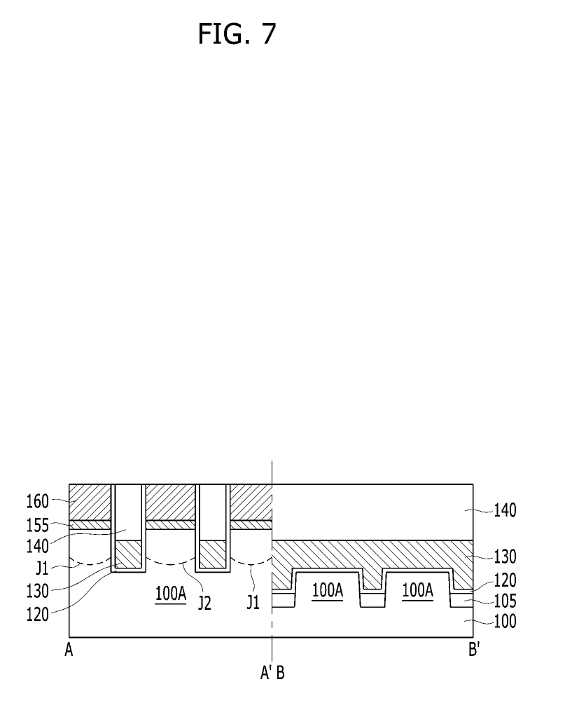

FIGS. 1 to 7 are views explaining an example of a transistor and an example of a method for fabricating the same in accordance with an implementation. Specifically, FIG. 1 is a plan view explaining the transistor of the implementation, and FIG. 7 is a cross-sectional view taken along lines A-A′ and B-B′ of FIG. 1. FIGS. 2 to 6 are cross-sectional views explaining intermediate processes for fabricating the transistor of FIGS. 1 and 7. The following description will be made based on the cross-sectional views, and further based on the plan view if necessary.

First, the fabricating method is described.

Referring to FIGS. 1 and 2, a semiconductor substrate 100 is provided. The semiconductor substrate 100 may include at least one of various semiconductor materials such as Si, etc. Also, the semiconductor substrate 100 may be formed of or include a crystalline semiconductor material.

Then, a hard mask layer 110 may be formed over the semiconductor substrate 100. Next, an isolation layer 105 may be formed by forming an isolation trench which defines an active region 100A in the semiconductor substrate 100 by selectively etching the hard mask layer 110 and the semiconductor substrate 100, and filling an insulating material in the isolation trench. For example, the hard mask layer 110 may be formed of or include a silicon nitride, and the isolation layer 105 may be formed of or include a silicon oxide. In this implementation, the active region 100A may extend along a first direction parallel to the line A-A′, and a plurality of the active regions 100A may be arranged to be spaced apart from each other along a second direction parallel to the line B-B′ which is different from the first direction along the line A-A′ and may be, for example, substantially perpendicular to the first direction along the line A-A′. In implementations, shapes, numbers and arrangement of the active regions 100A may be changed in various ways.

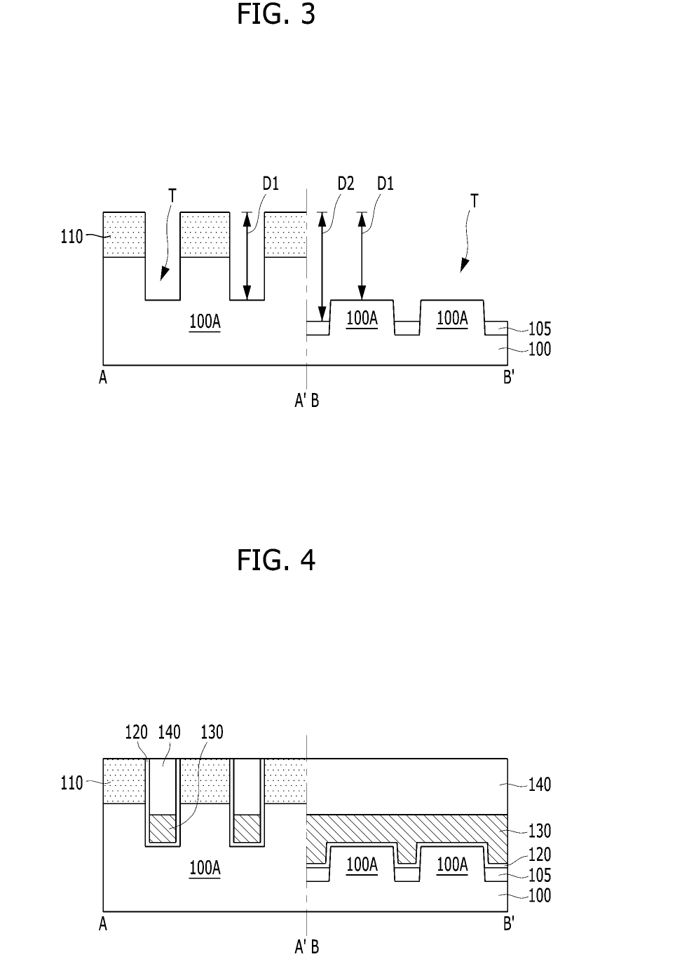

Referring to FIGS. 1 and 3, a gate trench T extending in the second direction to cross the active region 100A may be formed by selectively etching the active region 100A and the isolation layer 105 of a region where a gate 130 is to be formed. In this implementation, a plurality of the gate trenches T may be arranged to be spaced apart from each other along the first direction, and the gate trench T may cross all of the active regions 100A arranged along the second direction. However, shapes, numbers and arrangement of the gate trenches T may be changed in various ways.

When etching the active region 100A and the isolation layer 105 for forming the gate trench T, the isolation layer 105 may be etched more deeply compared to the active region 100A. That is, a depth D2 of the gate trench T located over the isolation layer 105 may be greater than a depth D1 of the gate trench T located over the active region 100A. Therefore, a part of the active region 100A may protrude over the isolation layer 105 in a region where the gate trench T is formed. For convenience of description, the part of the active region 100A which partially overlaps or intersects with the gate trench T and protrudes over the isolation layer 105 may be referred to as a protruding portion of the active region 100A. In other implementations, the depth D2 of the gate trench T located over the isolation layer 105 may be changed in various ways.

Referring to FIGS. 1 and 4, a gate insulating layer 120 may be formed along an inner wall of the gate trench T, and then, the gate 130 filling a part of the gate trench T may be formed.

The gate 130 may be formed by depositing a conductive material such as a metal, a metal nitride, a polysilicon doped with impurities or the like, over a resultant structure including the gate trench T, and performing an etch back process until the conductive material has a targeted or desired height. In this implementation, the gate 130 has a shape which is filled in the part of the gate trench T. In other implementations, the gate 130 may fill a whole of the gate trench T, or protrude over the semiconductor substrate 100 while filling the whole of the gate trench T. Since the gate 130 surrounds the protruding portion of the active region 100A located under the gate trench T, a contact area between the gate 130 and the active region 100A may be increased in the second direction.

Then, a gate protective layer 140 may be formed over the gate 130. When the gate 130 fills the part of the gate trench T, the gate protective layer 140 may be located over the gate 130 and fill a remaining space of the gate trench T. The gate protective layer 140 may be formed by depositing an insulating material such as an oxide, a nitride or the like, over a resultant structure in which the gate 130 is formed, and performing a planarization process, for example, a CMP (Chemical Mechanical Polishing) process until the hard mask layer 110 is exposed.

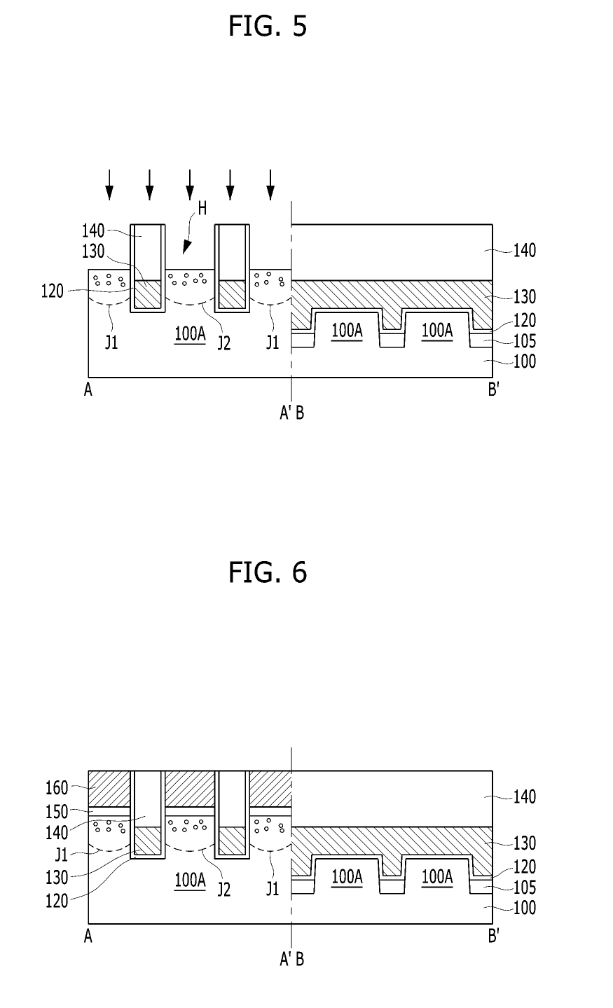

Referring to FIGS. 1 and 5, the hard mask layer 110 may be removed by a suitable technique including a wet etching or the like, to expose the active region 100A on both sides of the gate 130.

Then, impurities may be doped into the exposed active region 100A by an ion implantation process so that junction regions J1 and J2 are formed in the active region 100A on the both sides of the gate 130. In one implementation, high concentration of impurities is doped in the ion implantation process, because a resistance of the junction regions J1 and J2 decreases as concentration of the doped impurities increases. Here, by performing the ion implantation process at a relatively high temperature, for example, at a temperature of 450° C. or more, a surface portion of the active region 100A may be partially amorphized. By performing the ion implantation process at a relatively high temperature, an amorphous portion (see dotted shapes of FIG. 5) may be generated in a part of the surface portion of the active region 100A which is crystalline.

The above ion implantation process may be performed by implanting Si at a dose of about 5E14 ions/cm² to about 2E15 ions/cm² (i.e., from about 5×10¹⁴ ions/cm² to about 2×10¹⁵ ions/cm²) and an energy from about 1 KeV to about 10 KeV, by implanting C at a dose of about 1E14 ions/cm² to about 2E15 ions/cm² (i.e., from about 1×10¹⁴ ions/cm² to about 2×10¹⁵ ions/cm²) and an energy from about 1 KeV to about 20 KeV, by implanting as at a dose of about 1E15 ions/cm² to about 1E16 ions/cm² (i.e., from about 1×10¹⁵ ions/cm² to about 1×10¹⁶ ions/cm²) and an energy from about 1 KeV to about 10 KeV, or by implanting P at a dose of about 1E15 ions/cm² to about 2E16 ions/cm² (i.e., from about 1×10¹⁵ ions/cm² to about 2×10¹⁶ ions/cm²) and an energy from about 1 KeV to about 10 KeV.

Referring to FIGS. 1 and 6, a metal layer 150 and a conductive plug 160 may be formed in a space formed by the removal of the hard mask layer 110 described in FIG. 5.

The metal layer 150 may be used for forming a metal-semiconductor compound which has a low resistance, for example, a metal silicide in a heat treatment process which will be described later (see FIG. 7). The metal layer 150 may include at least one of various metal materials such as Ti, Co, or Ni, etc. The metal layer 150 may be formed by depositing a metal material over a resultant structure in which the hard mask layer 110 is removed, and performing an etch back process until the metal material has a targeted height.

The conductive plug 160 may be configured to electrically couple the junction regions J1 and J2 to another conductive pattern (not shown). Moreover, the conductive plug 160 may serve as a diffusion barrier which prevents a metal from diffusing from the metal layer 150 in the heat treatment process which will be described later (see FIG. 7). The conductive plug 160 may include a metal nitride such as TiN, etc. The conductive plug 160 may be formed by depositing a conductive material covering a resultant structure in which the metal layer 150 is formed, and performing a planarization process until the gate protective layer 140 is exposed.

Referring to FIGS. 1 and 7, the heat treatment process may be performed for a resultant structure of FIG. 6 to activate the impurities doped into the junction regions J1 and J2. During this heat treatment process, a metal-semiconductor compound layer 155 may be formed between the conductive plug 160 and the junction regions J1 and J2. When the semiconductor substrate 100 includes a silicon, the metal-semiconductor compound layer 155 may include a metal silicide such as a titanium silicide, etc. The metal-semiconductor compound layer 155 may serve to prevent inter-diffusion between the conductive plug 160 and the junction regions J1 or J2, and reduce an interfacial resistance between the conductive plug 160 and the junction regions J1 or J2.

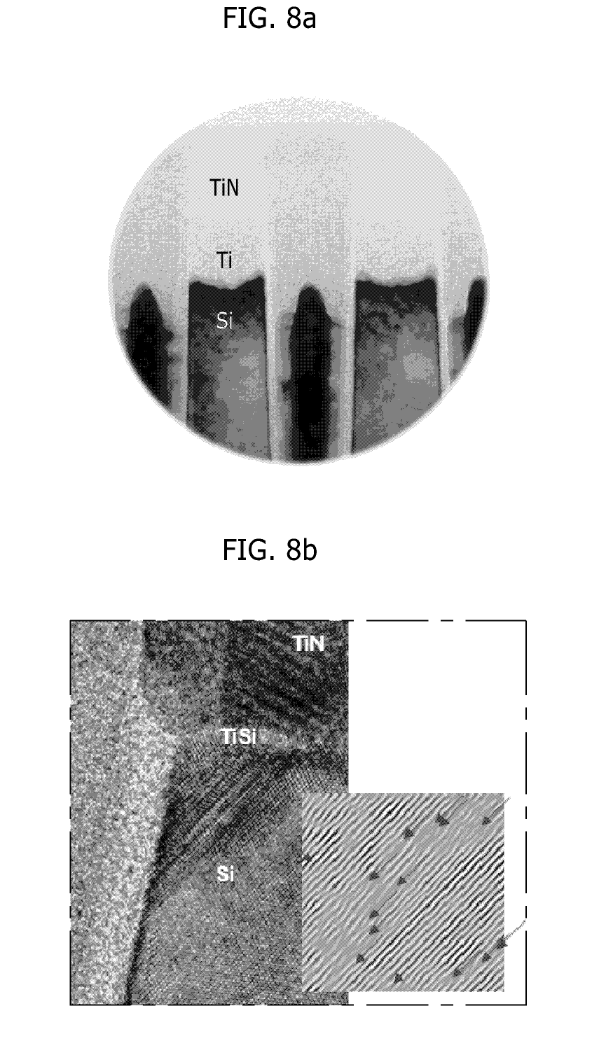

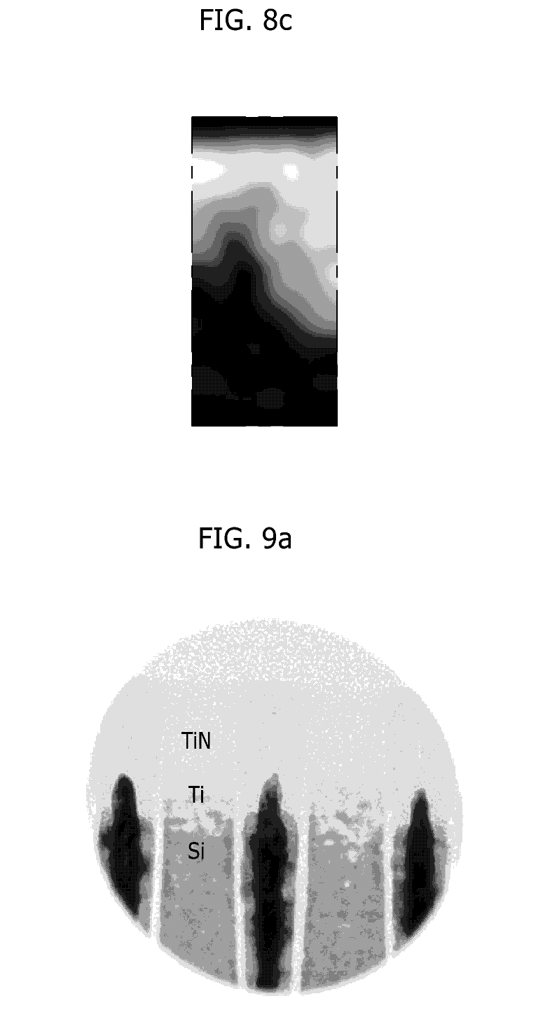

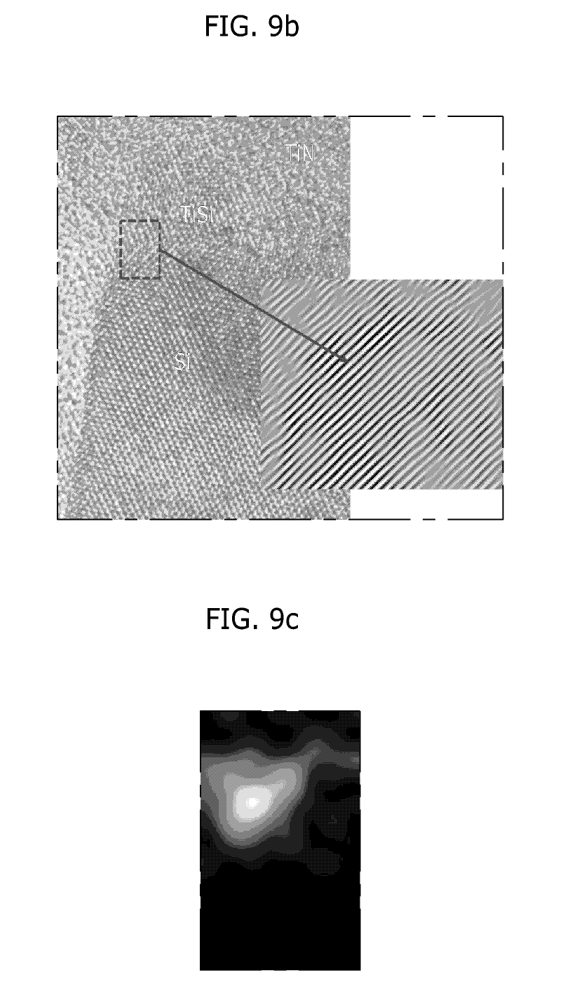

Furthermore, the surface portion of the active region 100A which is initially partially amorphized may be fully crystallized during the heat treatment process. If the surface portion of the active region 100A is in a fully amorphized state in the previous process, a rate of crystal growth in a <111> direction may be significantly slower than a rate of crystal growth in a <110> direction during the heat treatment process. Due to this, stacking faults in the <111> direction may be generated in the surface portion of the active region 100A. This is shown in the experimental result of FIGS. 8A to 8C which will be described later. These stacking faults may hinder activation of the impurities so that the resistance of the junction regions J1 and J2 increases. Also, these stacking faults may enable the formation of a non-uniform metal-semiconductor compound layer which deteriorates a resistance distribution of a transistor deteriorates. The above technical issue can be addressed by configuring the active region 100A to initially include a partially amorphized surface portion. In operation, when the surface portion of the active region 100A is in a partially amorphized state as in this implementation, the generation of the stacking faults in the <111> direction may be suppressed during the heat treatment process. This is shown in the experimental result of FIGS. 9A to 9C which will be described later. Since the stacking faults are suppressed, it is possible to enhance the activation of the impurities and enable the formation of a uniform metal-semiconductor compound layer. As a result, it is possible to reduce a resistance of a transistor and improve a resistance distribution of the transistor.

By the aforementioned processes, the semiconductor device of FIGS. 1 and 7 can be fabricated.

Referring back to FIGS. 1 and 7, the transistor of the implementation may include the semiconductor substrate 100 which includes the active region 100A defined by the isolation layer 105, the gate 130 which has a portion filled in the semiconductor substrate 100 and extends along the second direction to cross the active region 100A, the junction regions J1 and J2 which are formed in the active region 100A at the both sides of the gate 130 and contain high concentration of impurities while being fully crystallized, and the metal-semiconductor compound layer 155 and the conductive plug 160 which are sequentially stacked over the junction regions J1 and J2.

Effects derived from the above implementation will be described with reference to FIGS. 9A to 9C, compared to a comparative example of FIGS. 8A to 8C.

FIGS. 8A to 8C are views obtained during a fabricating process of a transistor in accordance with a comparative example.

FIG. 8A shows a case that a Ti layer and a TiN layer are formed over a fully amorphized Si layer.

FIG. 8B shows a structure obtained after performing a heat treatment on the structure of FIG. 8A. Referring to FIG. 8B, a plurality of stacking faults in a <111> direction are generated in the Si layer (see arrows).

FIG. 8C shows a TiSi layer of FIG. 8B in detail. Referring to FIG. 8C, a distribution of the TiSi layer is non-uniform.

FIGS. 9A to 9C are views obtained during a fabricating process of a transistor in accordance with an implementation.

FIG. 9A shows a case that a Ti layer and a TiN layer are formed over a partially amorphized Si layer, like FIG. 6.

FIG. 9B shows a structure obtained after performing a heat treatment on the structure of FIG. 9A. Referring to FIG. 9B, stacking faults do not exist in the Si layer.

FIG. 9C shows a TiSi layer of FIG. 9B in detail. Referring to FIG. 9C, a distribution of the TiSi layer is uniform.

In short, by the implementation, a Si layer which is fully crystallized and free from stacking faults can be formed by depositing a Ti layer and the like over a partially amorphized Si layer and performing a heat treatment. Therefore, it is possible to increase a degree of activation of impurities and form a TiSi layer having a uniform distribution. As a result, it is possible to reduce a resistance of a transistor while improving a resistance distribution of the transistor, thereby improving operating characteristics of the transistor such as an increase in an operating current.

Furthermore, when a contact area between a gate and an active region increases as in the implementation, the operating current of the transistor may be further increased, so the operating characteristics of the transistor may be further improved.

The above transistor may be used in various electronic devices including a semiconductor memory. For example, the semiconductor memory may include a cell array in which a plurality of memory cells for storing data are arranged, and each of the memory cells may include a memory element which stores data and an access element which controls an access to the memory element. The above transistor may be used as this access element. The above transistor may be coupled to the memory element which requires a high operating current, for example, a variable resistance element which requires a high current during switching between a high resistance state and a low resistance state such as a magnetic resistance element, etc. This will be exemplarily described with reference to drawings.

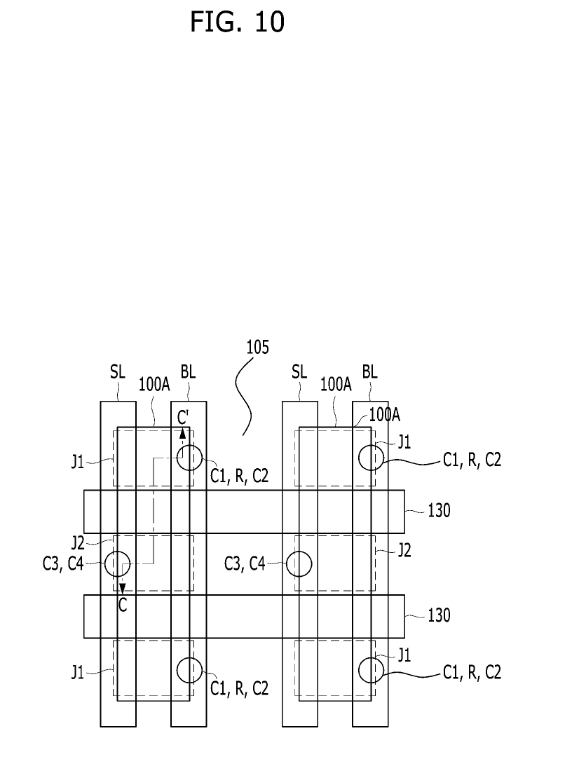

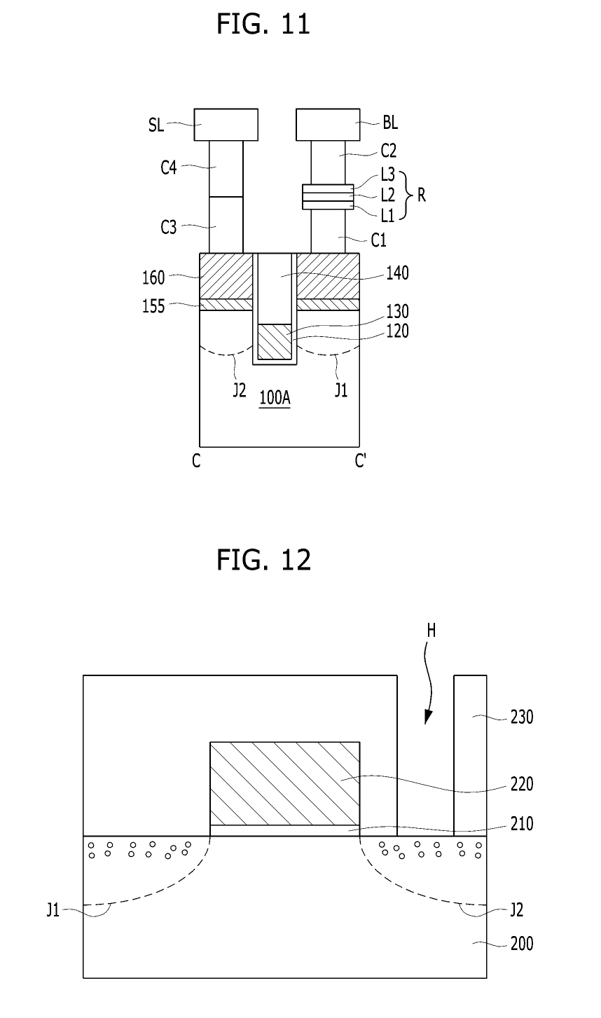

FIG. 10 is a plan view explaining a semiconductor memory in accordance with an implementation, and FIG. 11 is a cross-sectional view taken along a line C-C′ of FIG. 10.

Referring to FIGS. 10 and 11, the semiconductor memory of the implementation may include the transistor of FIGS. 1 and 7, a variable resistance element R which has a bottom end coupled to one of the junction regions J1 and J2 of the transistor, for example, a first junction region J1 located at both sides of adjacent two gates 130 in the first direction, a bit line BL coupled to a top end of the variable resistance element R, and a source line SL which has a bottom end coupled to the other of the junction regions J1 and J2 of the transistor, for example, a second junction region J2 located between the adjacent two gates 130 in the first direction.

The variable resistance element R may be coupled to the first junction region J1 through a first contact C1 penetrating an interlayer dielectric layer (not shown), and the bit line BL may be coupled to the variable resistance element R through a second contact C2 penetrating an interlayer dielectric layer (not shown). The source line SL may be coupled to the second junction region J2 through a third contact C3 and a fourth contact C4 penetrating an interlayer dielectric layer (not shown). The first contact C1 and the third contact C3 may be formed in a same process which includes etching and filling a conductive material by using the same mask. Similarly, the second contact C2 and the fourth contact C4 may be formed in a same process.

Here, the first contact C1, the variable resistance element R, the second contact C2 and the bit line BL may be formed close to one side, for example, a right side, of the active region 100A in the second direction. On the other hand, the third contact C3, the fourth contact C4 and the source line SL may be formed close to the other side, for example, a left side, of the active region 100A in the second direction. Thus, an interval between a stack structure of the first contact C1, the variable resistance element R, the second contact C2 and the bit line BL and another stack structure of the third contact C3, the fourth contact C4 and the source line SL may be secured so that an electrical short between the two stack structures is prevented.

Meanwhile, the variable resistance element R may be switched between different resistance states according to an applied voltage or current through the transistor coupled to the bottom end of the variable resistance element R and the bit line BL coupled to the top end of the variable resistance element R. The variable resistance element R may have a single-layered structure or a multi-layered structure including various materials used in an RRAM, a PRAM, an FRAM, an MRAM, or the like, for example, a transition metal oxide, a metal oxide such as a perovskite-based material, a phase change material such as a chalcogenide-based material, a ferroelectric material, or a ferromagnetic material, etc. The variable resistance element R may store different data according to its resistance state.

In this implementation, the variable resistance element R may include an MTJ (Magnetic Tunnel Junction) element including a first magnetic layer L1, a tunnel barrier layer L2 and a second magnetic layer L3. In this case, one of the first and second magnetic layers L1 and L3 may serve as a pinned layer which has a pinned magnetization direction, and the other of the first and second magnetic layers L1 and L3 may serve as a free layer which has a variable magnetization direction. Each of the first and second magnetic layers L1 and L3 may have a single-layered structure or a multi-layered structure including various ferromagnetic materials such as an Fe—Pt alloy, an Fe—Pd alloy, a Co—Pd alloy, a Co—Pt alloy, an Fe—Ni—Pt alloy, a Co—Fe—Pt alloy, or a Co—Ni—Pt alloy, etc. The tunnel barrier layer L2 may change the magnetization direction of the free layer by tunneling of electrons. The tunnel barrier layer L2 may have a single-layered structure or a multi-layered structure including an oxide such as Al₂O₃, MgO, CaO, SrO, TiO, VO, or NbO, etc. When the magnetization directions of the free layer and the pinned layer are parallel to each other, the variable resistance element R may be in a low resistance state. On the other hand, when the magnetization directions of the free layer and the pinned layer are anti-parallel to each other, the variable resistance element R may be in a high resistance state. Here, a relatively high current may be required to change the magnetization direction of the free layer, and this requirement may be satisfied by using the transistor of the implementation.

Other implementations are possible. For example, the transistor can be coupled to various memory elements, for example, a capacitor, which can store data, instead of the variable resistance element R.

The above semiconductor memory may be fabricated by using the transistor which has improved characteristics including the increasedoperating current. Therefore, operating characteristics of the semiconductor memory may be improved.

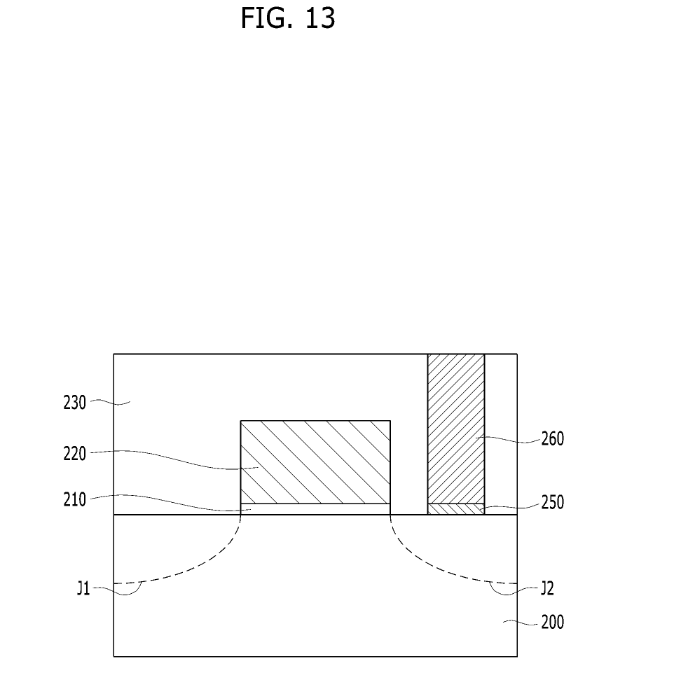

Meanwhile, shapes of the transistor may be changed in various ways. For example, a gate may not be buried in a semiconductor substrate. This will be exemplarily described with reference to FIGS. 12 and 13.

FIGS. 12 and 13 are cross-sectional views explaining a transistor and an example of a method for fabricating the same in accordance with another implementation.

Referring to FIG. 12, a semiconductor substrate 200 may be provided, and a gate 220 insulated from the semiconductor substrate 200 by a gate insulating layer 210 may be formed over the semiconductor substrate 200.

Junction regions J1 and J2 may formed in the semiconductor substrate 200 on both sides of the gate 220 by an ion implantation process. Here, by performing the ion implantation process at a relatively high temperature, for example, at a temperature of 450° C. or more, a surface portion of the junction regions J1 and J2 may be partially amorphized (see dotted shapes of FIG. 12).

An interlayer dielectric layer 230 covering the semiconductor substrate 200 and the gate 220 may be formed, and a hole H exposing one of the junction regions J1 and J2, for example, a second junction region J2 may be formed by selectively etching the interlayer dielectric layer 230.

Referring to FIG. 13, a metal layer (not shown) may be formed in a lower portion of the hole H1 and a conductive plug 260 formed of or including a metal nitride and the like may be formed over the metal layer. Then, a heat treatment process is performed on the metal layer and the conductive plug 260 to form a metal-semiconductor compound layer 250 such as a metal silicide and the like between the second junction region J2 and the conductive plug 260.

As described above, during the heat treatment process, the surface portion of the junction regions J1 and J2 which has been partially amorphized may be fully crystallized. Therefore, it is possible to obtain a transistor having a low resistance and an improved resistance distribution.

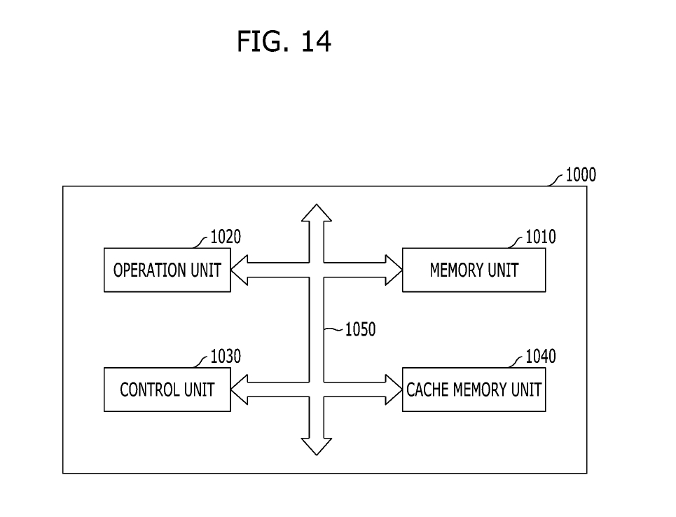

The above and other memory circuits or semiconductor devices based on the disclosed technology can be used in a range of devices or systems. FIGS. 14-18 provide some examples of devices or systems that can implement a memory circuit in accordance with an embodiment disclosed herein.

FIG. 14 is an example of configuration diagram of a microprocessor implementing memory circuitry based on the disclosed technology.

Referring to FIG. 14, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

At least one of the memory unit 1010, the operation unit 1020 and the control unit 1030 may include one or more of the above-described semiconductor devices in accordance with the implementations. For example, at least one of the memory unit 1010, the operation unit 1020 and the control unit 1030 may include a transistor comprising a semiconductor substrate in which a gate is formed; a junction region formed in the semiconductor substrate of a side of the gate; and a metal-semiconductor compound layer formed over the junction region, and wherein the junction region is in a fully crystallized state. Through this, operating characteristics of at least one of the memory unit 1010, the operation unit 1020 and the control unit 1030 may be improved. As a consequence, operating characteristics of the microprocessor 1000 may be improved.

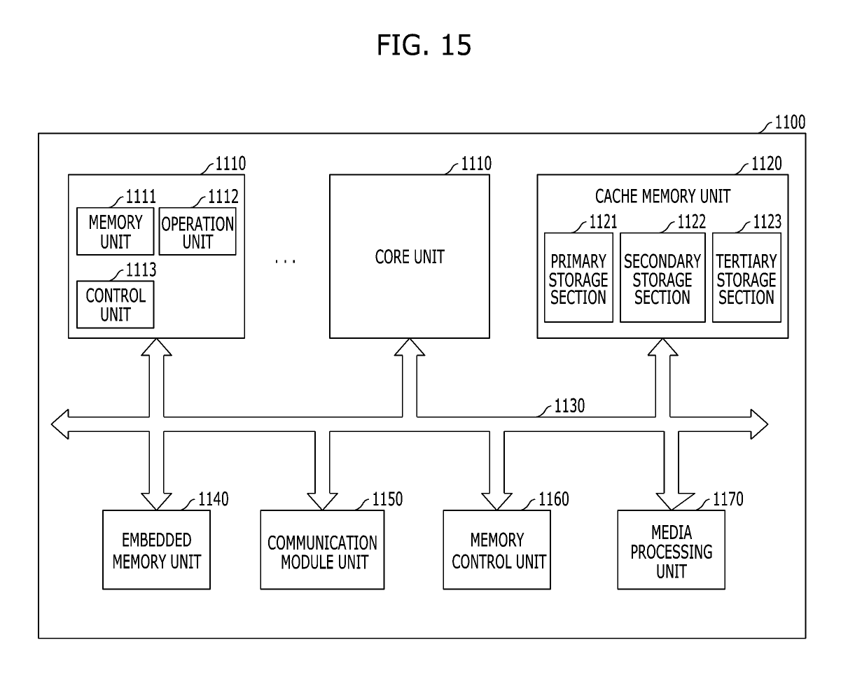

FIG. 15 is an example of configuration diagram of a processor implementing memory circuitry based on the disclosed technology.

Referring to FIG. 15, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest.

Although it was shown in FIG. 15 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

At least one of the cache memory unit 1120, the core unit 1110 and the bus interface 1130 may include one or more of the above-described semiconductor devices in accordance with the implementations. For example, at least one of the cache memory unit 1120, the core unit 1110 and the bus interface 1130 may include a transistor comprising a semiconductor substrate in which a gate is formed; a junction region formed in the semiconductor substrate of a side of the gate; and a metal-semiconductor compound layer formed over the junction region, and wherein the junction region is in a fully crystallized state. Through this, operating characteristics of at least one of the cache memory unit 1120, the core unit 1110 and the bus interface 1130 may be improved. As a consequence, operating characteristics of the processor 1100 may be improved.

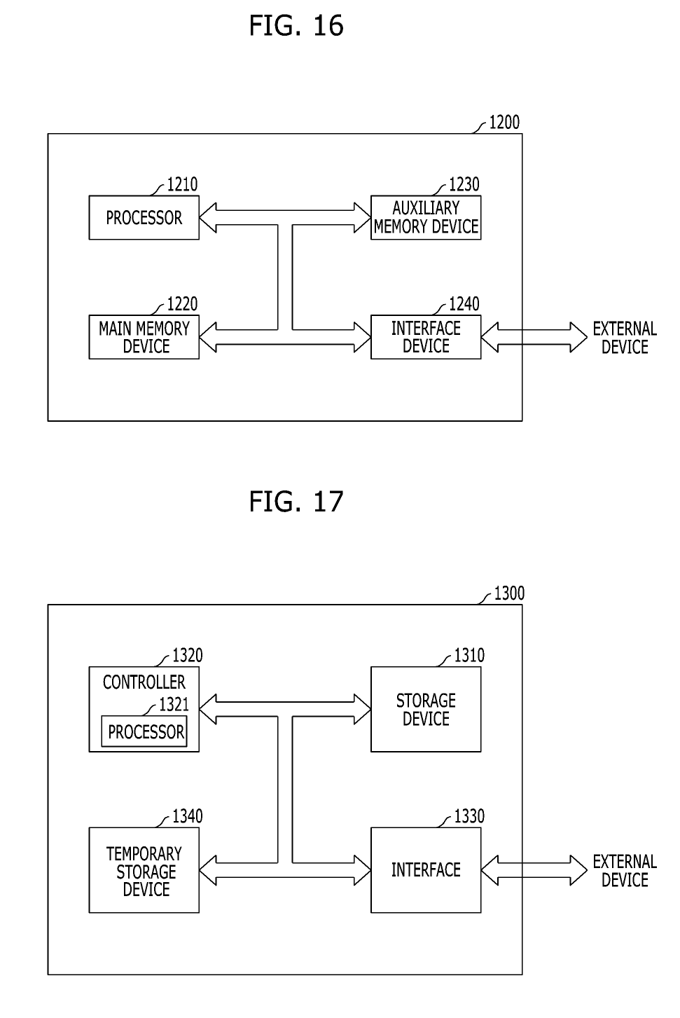

FIG. 16 is an example of configuration diagram of a system implementing memory circuitry based on the disclosed technology.

Referring to FIG. 16, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data.

Also, the auxiliary memory device 1230 may further include a data storage system (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 17) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

At least one of the processor 1210, the main memory device 1220, the auxiliary memory device 1230 and the interface device 1240 may include a transistor comprising a semiconductor substrate in which a gate is formed; a junction region formed in the semiconductor substrate of a side of the gate; and a metal-semiconductor compound layer formed over the junction region, and wherein the junction region is in a fully crystallized state. Through this, operating characteristics of at least one of the processor 1210, the main memory device 1220, the auxiliary memory device 1230 and the interface device 1240 may be improved. As a consequence, operating characteristics of the system 1200 may be improved.

FIG. 17 is an example of configuration diagram of a data storage system implementing memory circuitry based on the disclosed technology.

Referring to FIG. 17, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system.

At least one of the storage device 1310, the controller 1320, the interface 1330 and the temporary storage device 1340 may include one or more of the above-described semiconductor devices in accordance with the implementations. For example, at least one of the storage device 1310, the controller 1320, the interface 1330 and the temporary storage device 1340 may include a transistor comprising a semiconductor substrate in which a gate is formed; a junction region formed in the semiconductor substrate of a side of the gate; and a metal-semiconductor compound layer formed over the junction region, and wherein the junction region is in a fully crystallized state. Through this, operating characteristics of at least one of the storage device 1310, the controller 1320, the interface 1330 and the temporary storage device 1340 may be improved. As a consequence, operating characteristics of the data storage system 1300 may be improved.

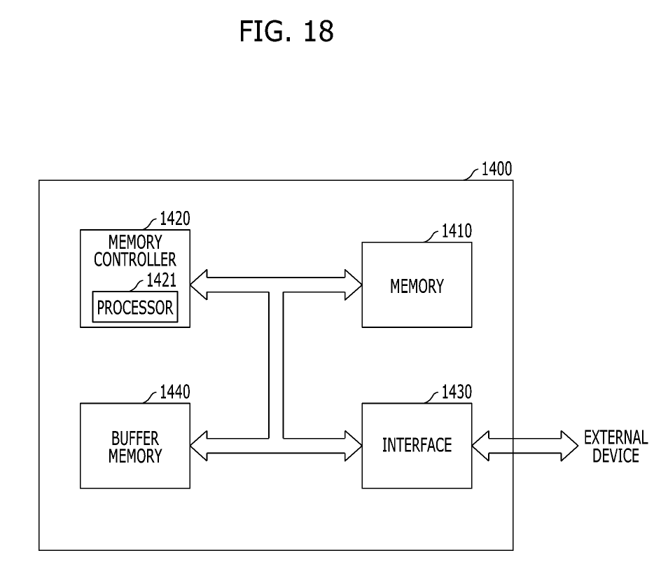

FIG. 18 is an example of configuration diagram of a memory system implementing memory circuitry based on the disclosed technology.

Referring to FIG. 18, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

At least one of the memory 1410, the memory controller 1420, the interface 1430 and the buffer memory 1440 may include one or more of the above-described semiconductor devices in accordance with the implementations. For example, at least one of the memory 1410, the memory controller 1420, the interface 1430 and the buffer memory 1440 may include a transistor comprising a semiconductor substrate in which a gate is formed; a junction region formed in the semiconductor substrate of a side of the gate; and a metal-semiconductor compound layer formed over the junction region, and wherein the junction region is in a fully crystallized state. Through this, operating characteristics of at least one of the memory 1410, the memory controller 1420, the interface 1430 and the buffer memory 1440 may be improved. As a consequence, operating characteristics of the memory system 1400 may be improved.

Features in the above examples of electronic devices or systems in FIGS. 14-18 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. A method for fabricating an electronic device comprising a transistor, comprising:
providing a semiconductor substrate in which a gate is formed;
forming a junction region which is partially amorphized in the semiconductor substrate at a side of the gate;
forming a metal layer over the junction region; and
performing a heat treatment process on the metal layer to change the metal layer into a metal-semiconductor compound layer while crystallizing the junction region.

2. The method of claim 1, wherein the forming of the junction region includes performing an ion implantation process at a temperature at or higher than 450° C.

3. The method of claim 2, wherein the performing of the ion implantation process includes implanting Si at a dose of 5×10¹⁴ to 2×10¹⁵ ions/cm² and an energy from 1 KeV to 10 KeV.

4. The method of claim 2, wherein the performing of the ion implantation process includes implanting C at a dose of 1×10¹⁴ to 2×10¹⁵ ions/cm² and an energy from 1 KeV to 20 KeV.

5. The method of claim 2, wherein the performing of the ion implantation process includes implanting As at a dose of 1×10¹⁵ to 1×10¹⁶ ions/cm² and an energy from 1 KeV to 10 KeV.

6. The method of claim 2, wherein performing of the ion implantation process includes implanting P at a dose of 1×10¹⁵ to 2×10¹⁶ ions/cm² and an energy from 1 KeV to 10 keV.

7. The method of claim 1, wherein the metal-semiconductor compound layer includes a metal silicide.

8. The method of claim 1, further comprising:
forming a conductive plug over the metal layer after the forming the metal layer and before the performing the heat treatment process.

9. The method of claim 8, wherein the conductive plug includes a metal nitride.

10. The method of claim 1, further comprising:
forming a variable resistance element which is electrically coupled to the metal-semiconductor compound layer after the performing the heat treatment process.

11. The method of claim 10, wherein the variable resistance element includes two magnetic layers and a tunnel barrier layer interposed between the two magnetic layers.

12. An electronic device comprising a transistor, wherein the transistor includes:
a semiconductor substrate in which a gate is formed;
a junction region formed in the semiconductor substrate at a side of the gate; and
a metal-semiconductor compound layer formed over the junction region, and
wherein the junction region is in a crystallized state.

13. The electronic device of claim 12, further comprising:
a variable resistance element electrically coupled to the metal-semiconductor compound layer.

14. The electronic device of claim 13, wherein the variable resistance element includes two magnetic layers and tunnel barrier layer interposed between the two magnetic layers.

15. The electronic device according to claim 12, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the transistor is part of at least one of the control unit, the operation unit and the memory unit in the microprocessor.

16. The electronic device according to claim 12, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the transistor is part of at least one of the core unit, the cache memory unit and the bus interface in the processor.

17. The electronic device according to claim 12, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the transistor is part of at least one of the processor, the auxiliary memory device, the main memory device and the interface device in the processing system.

18. The electronic device according to claim 12, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the transistor is part of at least one of the controller, the storage device, the temporary storage device and the interface in the data storage system.

19. The electronic device according to claim 12, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the transistor is part of at least one of the memory controller, the memory, the buffer memory and the interface in the memory system.
